(19) United States
(12) Patent Application Publication
(10) Pub. No.: US 2026/0026266 A1
(43) Pub. Date: Jan. 22, 2026

(54) RESISTIVE MEMORY CELL AND FABRICATION METHOD THEREOF

(71) Applicant: UNITED MICROELECTRONICS CORP., Hsin-Chu City (TW)

(72) Inventors: Shih-Ming Lin, Kaohsiung City (TW); Yu-Lung Shih, Tainan City (TW); Kun-Ju Li, Tainan City (TW)

(73) Assignee: UNITED MICROELECTRONICS CORP., Hsin-Chu City (TW)

(21) Appl. No.: 18/792,510

(22) Filed: Aug. 1, 2024

(30) Foreign Application Priority Data
Jul. 16, 2024 (TW) 113126544

(51) Int. Cl. H10N 70/00; H10B 63/00; H10N 70/20

(52) U.S. Cl. CPC H10N 70/828; H10B 63/00; H10N 70/043; H10N 70/24; H10N 70/8833

(57) ABSTRACT

A resistive memory cell includes a substrate, a bottom electrode layer disposed on the substrate, a switching layer disposed on the bottom electrode layer, and a top electrode layer disposed on the switching layer. The switching layer includes a localized doped region. The localized doped region has a composition that is different from a composition of the switching layer outside the localized doped region.

### BACKGROUND OF THE INVENTION

### 1. Field of the Invention

The present invention relates to the field of semiconductor technology, and in particular, to an improved resistive memory cell and a manufacturing method thereof.

### 2. Description of the Prior Art

Resistive random-access memory (RRAM) cells typically consist of two conductive electrodes sandwiching a switching layer, which allows the memory cell to switch between a high-resistance state (HRS), representing a logical “0,” and a low-resistance state (LRS), representing a logical “1.”

RRAM operation relies on the formation and breaking of conductive filaments within the switching layer. These filaments create low-resistance paths between the electrodes, driving the cell to the LRS. However, the unpredictable number and distribution of these filaments lead to unstable electrical characteristics, such as variations in the voltages required to set (switch to LRS) or reset (switch to HRS) the cell.

### SUMMARY OF THE INVENTION

It is one object of the present invention to provide an improved resistive memory cell and a manufacturing method thereof to solve the deficiencies or shortcomings of the existing technology.

One aspect of the invention provides a resistive memory cell including a substrate; a bottom electrode layer disposed on the substrate; a switching layer disposed on the bottom electrode layer, wherein the switching layer comprises a localized doped region, wherein the localized doped region has a composition that is different from a composition of the switching layer outside the localized doped region; and a top electrode layer disposed on the switching layer.

According to some embodiments, the localized doped region comprises a metal oxide that does not contain a stoichiometric amount of oxygen.

According to some embodiments, the localized doped region comprises a plurality of oxygen vacancies.

According to some embodiments, the switching layer comprises Ta₂O₅, and wherein the localized doped region comprises Ta₂O₅₋ₓ, wherein x is greater than or equal to 0.25.

According to some embodiments, the top electrode layer is in direct contact with the localized doped region.

According to some embodiments, the localized doped region extends into the switching layer to a depth that is smaller than a thickness of the switching layer.

According to some embodiments, the localized doped region has an inverted triangle sectional profile.

According to some embodiments, the localized doped region comprises a lower layer and an upper layer, wherein the lower layer comprises a first sub-stoichiometric metal oxide and the upper layer comprises a second sub-stoichiometric metal oxide that is different from the first sub-stoichiometric metal oxide.

According to some embodiments, the first sub-stoichiometric metal oxide comprises ZnOₓ, wherein x is smaller than 1, and wherein the second sub-stoichiometric metal oxide comprises Ta₂O₅₋ₓ, wherein x is greater than or equal to 0.25.

According to some embodiments, the switching layer comprises Ta₂O₅, HfO₂, or TiO₂, and wherein the top electrode layer comprises TaN, TiN, Pt, It, Ru, or W.

Another aspect of the invention provides a method for forming a resistive memory cell. A substrate is provided. A bottom electrode layer is formed on the substrate. A switching layer is formed on the bottom electrode layer. An ion implantation process is performed to form a localized doped region in the switching layer. The localized doped region is then subjected to an annealing process, wherein the localized doped region has a composition that is different from a composition of the switching layer outside the localized doped region. A top electrode layer is formed on the switching layer.

According to some embodiments, the localized doped region comprises a metal oxide that does not contain a stoichiometric amount of oxygen.

According to some embodiments, the localized doped region comprises a plurality of oxygen vacancies.

According to some embodiments, the switching layer comprises Ta₂O₅, and wherein the localized doped region comprises Ta₂O₅₋ₓ, wherein x is greater than or equal to 0.25.

According to some embodiments, the top electrode layer is in direct contact with the localized doped region.

According to some embodiments, the localized doped region extends into the switching layer to a depth that is smaller than a thickness of the switching layer.

According to some embodiments, the localized doped region has an inverted triangle sectional profile.

According to some embodiments, the localized doped region comprises a lower layer and an upper layer, wherein the lower layer comprises a first sub-stoichiometric metal oxide and the upper layer comprises a second sub-stoichiometric metal oxide that is different from the first sub-stoichiometric metal oxide.

According to some embodiments, the first sub-stoichiometric metal oxide comprises ZnOₓ, wherein x is smaller than 1, and wherein the second sub-stoichiometric metal oxide comprises Ta₂O₅₋ₓ, wherein x is greater than or equal to 0.25.

According to some embodiments, the switching layer comprises Ta₂O₅, HfO₂, or TiO₂, and wherein the top electrode layer comprises TaN, TiN, Pt, It, Ru, or W.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic cross-sectional diagrams showing a method of forming a resistive memory cell according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

Please refer to FIG. 1 to FIG. 5, which are schematic cross-sectional diagrams showing a method of forming a resistive memory cell according to an embodiment of the present invention. As shown in FIG. 1, a substrate 100 is first provided. For example, the substrate 100 may be a silicon substrate, but is not limited thereto. It should be understood that structures such as dielectric layers and metal wires may be formed on the substrate 100, which are not shown for the sake of simplicity. Next, a bottom electrode layer 101 is formed on the substrate 100. For example, the bottom electrode layer 101 may comprise Ti, TN, Ta, TaN or a combination thereof, but is not limited thereto. A switching layer 102 is formed on the bottom electrode layer 101. According to an embodiment of the present invention, the switching layer 102 may comprise Ta₂O₅, HfO₂ or TiO₂, but is not limited thereto. For example, the switching layer 102 may be a Ta₂O₅ layer.

Subsequently, a photoresist pattern 110 is formed on the switching layer 102, which includes a first opening 110a, which exposes a central region of the switching layer 102. According to an embodiment of the present invention, the width of the first opening 110a is FR1, and the distance from the edge of the first opening 110a to the edge of the switching layer 102 is PR1.

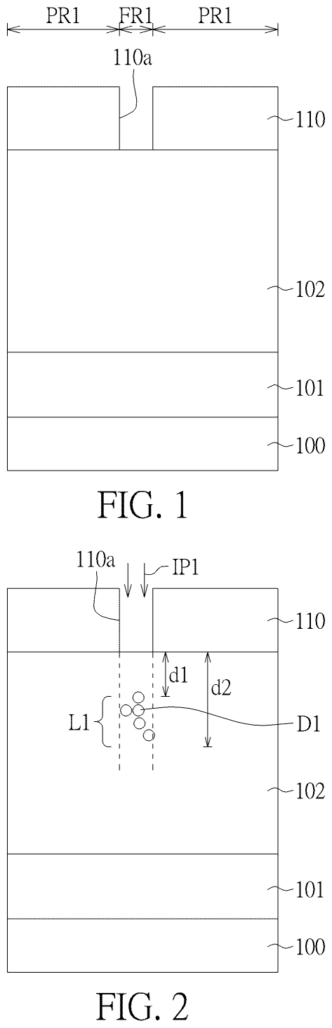

As shown in FIG. 2, the first ion implantation process IP1 is performed, and the first dopant D1 is implanted into the switching layer 102 through the first opening 110a of the photoresist pattern 110. According to an embodiment of the present invention, the first dopant D1 may be, for example, Ta ions or Zn ions, but is not limited thereto. According to an embodiment of the present invention, the ion implantation energy of the first ion implantation process IP1 is controlled at E1 to control the main distribution range of the first dopant D1 in the lower doping region (hereinafter referred to as The lower layer) L1 with a distribution width approximately equal to the width FR1 of the first opening 110a.

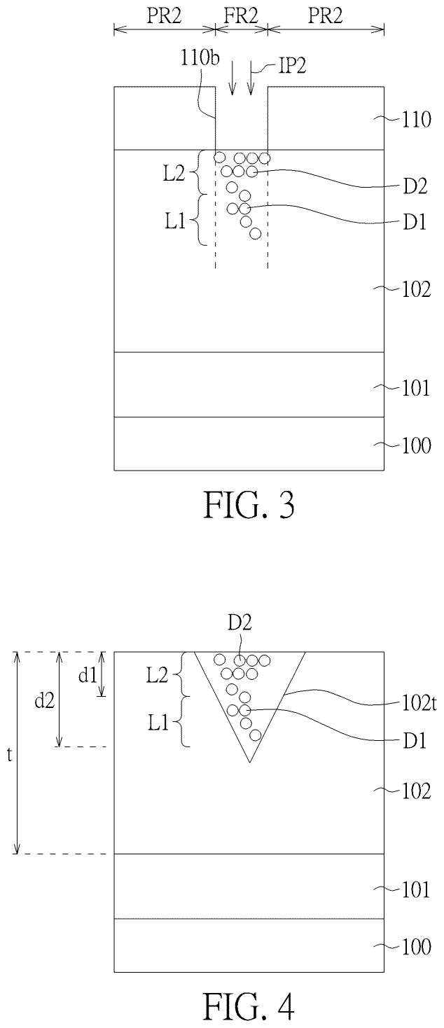

As shown in FIG. 3, after the ion bombardment of the first ion implantation process IP1, the first opening 110a will be expanded into a larger second opening 110b with a width FR2, where the width FR2 is greater than the width FR1. The distance from the edge of the opening 110b to the edge of the switching layer 102 is PR2, where the distance PR2 is smaller than the distance PR1. The second ion implantation process IP2 is then performed, and the second dopant D2 is implanted into the switching layer 102 through the second opening 110b of the photoresist pattern 110. According to an embodiment of the present invention, the second dopant D2 may be the same as the first dopant D1. For example, the first dopant D1 and the second dopant D2 are both Ta ions.

According to an embodiment of the present invention, the ion implantation energy of the second ion implantation process IP2 is controlled at E2, where E2 is smaller than E1, so as to control the main distribution range of the second dopant D2 in the upper doping region (hereinafter referred to as the upper layer) L2 above the depth d1. The upper layer L2 may have a distribution width that is approximately equal to the width FR2 of the second opening 110b.

According to another embodiment of the present invention, the second dopant D2 may be different from the first dopant D1. For example, the second dopant D2 may be Ta ions, and the first dopant D1 may be Zn ions or other metals with relatively large Gibbs free energy. When the first dopant D1 is Zn ion, its ability to snatch oxygen is strong, forming a large number of oxygen vacancies, which become the main conductive filament path. During operation, electrons will tend to move to this position to maintain a single fixed conduction path.

As shown in FIG. 4, the lower layer L1 and the upper layer L2 together form a localized doped region 102t in the switching layer 102. According to an embodiment of the present invention, the localized doped region 102t has an inverted triangular cross-sectional profile. According to an embodiment of the present invention, the localized doped region 102t extends to a depth d2 of the switching layer 102, where the depth d2 is less than the entire thickness t of the switching layer 102. For example, the depth d2 is approximately one-half to one-quarter of the entire thickness t of the switching layer 102.

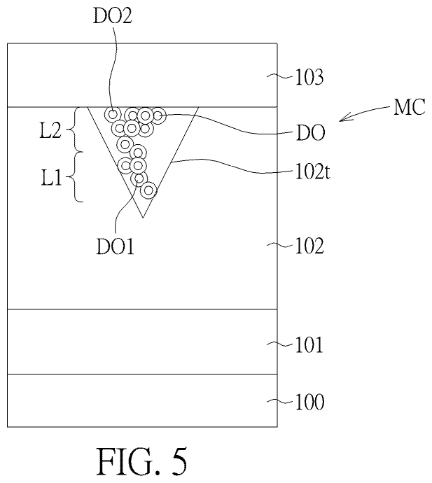

As shown in FIG. 5, the remaining photoresist pattern 110 is then removed, and an annealing process is performed on the localized doped region 102t to form a metal oxide DO that does not contain a stoichiometric amount of oxygen in the localized doped region 102t. At this point, the metal oxide composition in the localized doped region 102t is different from the metal oxide composition of the switching layer 102 outside the localized doped region 102t. According to an embodiment of the present invention, after the annealing process, the localized doped region 102t includes a plurality of oxygen vacancies. According to an embodiment of the present invention, for example, the switching layer 102 mainly includes Ta₂O₅, and the localized doped region 102t includes Ta₂O₅₋ₓ, where x is greater than or equal to 0.25.

According to another embodiment of the present invention, for example, the lower layer L1 of the localized doped region 102t includes a first sub-stoichiometric metal oxide DO1, and the upper layer L2 of the localized doped region 102t includes a second sub-stoichiometric metal oxide DO2 different from the first sub-stoichiometric metal oxide DO1. The term “sub-stoichiometric metal oxide” refers to a metal oxide that does not contain a stoichiometric amount of oxygen. In other words, the term “sub-stoichiometric metal oxide” refers to a metal oxide in which at least part of the oxygen has been removed, leaving oxygen vacancies. For example, the first sub-stoichiometric metal oxide DO1 includes ZnOₓ, where x is less than 1, and the second sub-stoichiometric metal oxide DO2 includes Ta₂O₅₋ₓ, where x is greater than or equal to 0.25.

Subsequently, a top electrode layer 103 is formed on the switching layer 102 to form a resistive memory cell MC. According to an embodiment of the present invention, the top electrode layer 103 directly contacts the localized doped region 102t of the switching layer 102. According to an embodiment of the present invention, for example, the top electrode layer may comprise TaN, TiN, Pt, It, Ru or W, but is not limited thereto.

Structurally, as shown in FIG. 5, the resistive memory cell MC comprises a substrate 100, a bottom electrode layer 101 disposed on the substrate 100, a switching layer 102 disposed on the bottom electrode layer 101, and a top electrode layer 103 disposed on the switching layer 102. The switching layer 102 comprises a localized doped region 102t. The composition of the localized doped region 102t is different from the composition of the switching layer 102 outside the localized doped region 102t. According to an embodiment of the present invention, the top electrode layer 103 directly contacts the localized doped region 102t. According to an embodiment of the present invention, the depth d1 of the localized doped region 102t extending into the switching layer 102 is less than the thickness t of the switching layer 102. According to an embodiment of the present invention, the localized doped region 102t has an inverted triangular cross-sectional profile.

According to an embodiment of the present invention, the switching layer 102 includes, for example, Ta₂O₅, HfO₂, or TiO₂. According to an embodiment of the present invention, the top electrode layer 103 includes, for example, TaN, TiN, Pt, It, Ru, or W.

According to an embodiment of the present invention, the localized doped region 102t includes a metal oxide that does not contain a stoichiometric amount of oxygen. According to an embodiment of the present invention, the localized doped region 102t includes a plurality of oxygen vacancies. According to an embodiment of the present invention, the switching layer 102 includes Ta₂O₅, and the localized doped region 102t includes, for example, Ta₂O₅₋ₓ, where x is greater than or equal to 0.25.

According to some embodiments of the present invention, the localized doped region 102t includes a lower layer L1 and an upper layer L2, wherein the lower layer L1 includes a first sub-stoichiometric metal oxide DO1 and the upper layer L2 includes a second sub-stoichiometric metal oxide DO2 different from the first sub-stoichiometric metal oxide DO1. According to an embodiment of the present invention, the first sub-stoichiometric metal oxide DO1 includes, for example, ZnOₓ, where x is less than 1, and the second sub-stoichiometric metal oxide DO2 includes, for example, Ta₂O₅₋ₓ, where x is greater than or equal to 0.25.

Through two ion implantation processes, the present invention forms a localized doped region 102t with an inverted triangular cross-sectional profile in the switching layer 102. The localized doped region 102t has a plurality of oxygen vacancies and becomes the main conductive filament path. During operation, electrons will tend to move to this position so as to maintain a single fixed conduction path, which improves the electrical characteristics of the memory device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive memory cell, comprising:
a substrate;
a bottom electrode layer disposed on the substrate;
a switching layer disposed on the bottom electrode layer, wherein the switching layer comprises a localized doped region, wherein the localized doped region has a composition that is different from a composition of the switching layer outside the localized doped region; and
a top electrode layer disposed on the switching layer.

2. The resistive memory cell according to claim 1, wherein the localized doped region comprises a metal oxide that does not contain a stoichiometric amount of oxygen.

3. The resistive memory cell according to claim 1, wherein the localized doped region comprises a plurality of oxygen vacancies.

4. The resistive memory cell according to claim 1, wherein the switching layer comprises Ta₂O₅, and wherein the localized doped region comprises Ta₂O₅₋ₓ, wherein x is greater than or equal to 0.25.

5. The resistive memory cell according to claim 1, wherein the top electrode layer is in direct contact with the localized doped region.

6. The resistive memory cell according to claim 1, wherein the localized doped region extends into the switching layer to a depth that is smaller than a thickness of the switching layer.

7. The resistive memory cell according to claim 1, wherein the localized doped region has an inverted triangle sectional profile.

8. The resistive memory cell according to claim 1, wherein the localized doped region comprises a lower layer and an upper layer, wherein the lower layer comprises a first sub-stoichiometric metal oxide and the upper layer comprises a second sub-stoichiometric metal oxide that is different from the first sub-stoichiometric metal oxide.

9. The resistive memory cell according to claim 8, wherein the first sub-stoichiometric metal oxide comprises ZnOₓ, wherein x is smaller than 1, and wherein the second sub-stoichiometric metal oxide comprises Ta₂O₅₋ₓ, wherein x is greater than or equal to 0.25.

10. The resistive memory cell according to claim 1, wherein the switching layer comprises Ta₂O₅, HfO₂, or TiO₂, and wherein the top electrode layer comprises TaN, TiN, Pt, It, Ru, or W.

11. A method for forming a resistive memory cell, comprising:
providing a substrate;
forming a bottom electrode layer on the substrate;
forming a switching layer on the bottom electrode layer;
performing an ion implantation process to form a localized doped region in the switching layer;
subjecting the localized doped region to an annealing process, wherein the localized doped region has a composition that is different from a composition of the switching layer outside the localized doped region; and
forming a top electrode layer on the switching layer.

12. The method according to claim 11, wherein the localized doped region comprises a metal oxide that does not contain a stoichiometric amount of oxygen.

13. The method according to claim 11, wherein the localized doped region comprises a plurality of oxygen vacancies.

14. The method according to claim 11, wherein the switching layer comprises Ta₂O₅, and wherein the localized doped region comprises Ta₂O₅₋ₓ, wherein x is greater than or equal to 0.25.

15. The method according to claim 11, wherein the top electrode layer is in direct contact with the localized doped region.

16. The method according to claim 11, wherein the localized doped region extends into the switching layer to a depth that is smaller than a thickness of the switching layer.

17. The method according to claim 11, wherein the localized doped region has an inverted triangle sectional profile.

18. The method according to claim 11, wherein the localized doped region comprises a lower layer and an upper layer, wherein the lower layer comprises a first sub-stoichiometric metal oxide and the upper layer comprises a second sub-stoichiometric metal oxide that is different from the first sub-stoichiometric metal oxide.

19. The method according to claim 18, wherein the first sub-stoichiometric metal oxide comprises ZnOₓ, wherein x is smaller than 1, and wherein the second sub-stoichiometric metal oxide comprises Ta₂O₅₋ₓ, wherein x is greater than or equal to 0.25.

20. The method according to claim 11, wherein the switching layer comprises Ta₂O₅, HfO₂, or TiO₂, and wherein the top electrode layer comprises TaN, TiN, Pt, It, Ru, or W.
